(19) United States
(12) Patent Application Publication
(10) Pub. No.: US 2011/0248243 A1
(43) Pub. Date: Oct. 13, 2011

(54) Carbon nanotube field effect transistor for printed flexible/rigid electronics

(75) Inventors: Yihong Chen, Austin, TX (US); Ray T. Chen, Austin, TX (US)

(73) Assignee: Omega Optics, Inc., Austin, TX (US)

(21) Appl. No.: 12/592,573

(22) Filed: Nov. 30, 2009

(51) Int. Cl. H01L 51/10; H01L 51/30; H01L 51/40

(52) U.S. Cl. 257/29; 438/151; 438/197; 257/E51.006; 257/E51.04; 257/E51.001; 977/938

(57) ABSTRACT

Methods and devices for manufacturing carbon nanotube based field effect transistors are disclosed including providing a substrate; printing a gate electrode layer onto the substrate and sintering and/or UV curing; printing a gate isolation layer onto the gate electrode and air drying and/or UV curing; printing one or more carbon nanotube channel layers onto the gate isolation layer, wherein each carbon nanotube channel layer is air dried prior to subsequent printings; and printing a source and drain electrode layer onto the one or more carbon nanotube channel layers and sintering and/or UV curing. Other embodiments are described and claimed.

### STATEMENT REGARDING FEDERALLY SPONSORED RESEARCH

The U.S. Government has a paid-up license in this invention and the right in limited circumstances to require the patent owner to license others on reasonable terms as provided for by the terms of the contract NNX09CA37C awarded by NASA.

### BACKGROUND OF THE INVENTION

1. Field of the Invention

This invention relates generally to the field of printed flexible or rigid electronics, and more specifically to methods and devices for the manufacture of carbon nanotube based field effect transistors (CNT-FETs).

2. Background of the Invention

Carbon nanotubes (CNT) have many unique electrical and mechanical properties. CNT based transistors are being investigated by many research groups (Tan et al., Nature, 1998 (393), Martel et al., Appl. Phys. Lett. 1998 (73), Rogers et al., RSC Chemistry World, 2008 July). Many devices are based on a single CNT as a channel placed between source and drain electrodes. These kinds of devices are difficult to prepare, requiring highly specialized equipment, including electron beam writing, to place the CNT and electrodes in position. For this reason, CNT based transistors have been kept in the research stage, rather than mass production.

Scientists have been investigating flexible alternatives to rigid crystalline semiconductor circuits for decades. Current state-of-the-art flexible electronics are based on organic or polymer materials, such as regioregular poly (3-hexylthiophene) derivatives and pentacene (Bao et al., J. Mater. Chem., 1999 (9), Wang et al., J. of Appl. Phys. 2003 (93)). The carrier (electron or hole) mobility of these materials is less than 0.1 cm²/V·s. Amorphous silicon shows a higher carrier mobility of ˜1 cm²/V·s (Meiling et al., Appl. Phys. Lett. 1997 (70)). However, it is still two orders of magnitude lower than conventional single crystal silicon. Such low carrier mobility limits the operating frequency of the organic or polymer based flexible electronics circuit to a few kHz. The low operating frequency makes this kind of electronics unsuitable for high operating frequency communications, such as flexible, active RF antenna and RFID, etc. John Rogers' group of the University of Illinois at Urbana-Champaign has shown that a web of carbon nanotubes deposited on a flexible plastic surface can form the basis of an electronic circuit containing scores of transistors with field effect mobility comparable to a silicon-wafer-based device. However, the fabrication procedure is complex and the unwanted metallic CNTs are unavoidable. Whether carbon nanotubes take over from organics will ultimately depend on cost.

### SUMMARY OF THE INVENTION

The primary objective of the invention is to provide an apparatus and manufacturing process for network based CNT, instead of single based CNT, field effect transistors for high speed applications, utilizing the ultra high carrier mobility of CNT.

The second objective of the invention is to eliminate the need for complex photolithography of traditional transistor fabrication by implementing a novel inkjet printing process, which significantly increases the throughput of the devices and enables low cost mass production.

The third objective of the invention is to fabricate the device on flexible substrates to facilitate the flexible conformal electronics.

The fourth objective of the invention is the room temperature process that avoids the high temperature processes associated with photolithography and chemical etching for the patterning of devices.

In one respect, disclosed is a method for manufacturing carbon nanotube based field effect transistors, the method comprising: providing a substrate; using a conductive fluid to print a gate electrode layer onto the substrate; sintering and/or UV curing the gate electrode layer; using a nonconductive fluid to print a gate isolation layer onto the gate electrode; air drying and/or UV curing the gate isolation layer; using a carbon nanotube solution to print one or more carbon nanotube channel layers onto the gate isolation layer, wherein each carbon nanotube channel layer is air dried prior to subsequent printings; using the conductive fluid to print a source and drain electrode layer onto the one or more carbon nanotube channel layers; and sintering and/or UV curing the source and drain electrode layer.

In another respect, disclosed is a method for manufacturing carbon nanotube based field effect transistors, the method comprising: providing a substrate; using a conductive fluid to print a source and drain electrode layer onto the substrate; sintering and/or UV curing the source and drain electrode layer; using a carbon nanotube solution to print one or more carbon nanotube channel layers onto the source and drain electrode layer, wherein each carbon nanotube channel layer is air dried prior to subsequent printings; using a nonconductive fluid to print a gate isolation layer onto the one or more carbon nanotube channel layers; air drying and/or UV curing the gate isolation layer; using the conductive fluid to print a gate electrode layer onto the gate isolation layer; and sintering and/or UV curing the gate electrode layer.

In another respect, disclosed is a semiconductor device comprising a carbon nanotube field effect transistor, where the carbon nanotube field effect transistor is fabricated by: providing a substrate; using a conductive fluid to print a gate electrode layer onto the substrate; sintering and/or UV curing the gate electrode layer; using a nonconductive fluid to print a gate isolation layer onto the gate electrode; air drying and/or UV curing the gate isolation layer; using a carbon nanotube solution to print one or more carbon nanotube channel layers onto the gate isolation layer, wherein each carbon nanotube channel layer is air dried prior to subsequent printings; using the conductive fluid to print a source and drain electrode layer onto the one or more carbon nanotube channel layers; and sintering and/or UV curing the source and drain electrode layer.

In yet another respect, disclosed is a semiconductor device comprising a carbon nanotube field effect transistor, where the carbon nanotube field effect transistor is fabricated by: providing a substrate; using a conductive fluid to print a source and drain electrode layer onto the substrate; sintering and/or UV curing the source and drain electrode layer; using a carbon nanotube solution to print one or more carbon nanotube channel layers onto the source and drain electrode layer, wherein each carbon nanotube channel layer is air dried prior to subsequent printings; using a nonconductive fluid to print a gate isolation layer onto the one or more carbon nanotube channel layers; air drying and/or UV curing the gate isolation layer; using the conductive fluid to print a gate electrode layer onto the gate isolation layer; and sintering and/or UV curing the gate electrode layer.

Numerous additional embodiments are also possible.

### BRIEF DESCRIPTION OF THE DRAWINGS

Other objects and advantages of the invention may become apparent upon reading the detailed description and upon reference to the accompanying drawings.

The drawings constitute a part of this specification and include exemplary embodiments of the present invention, which may be embodied in various forms. It is to be understood that in some instances various aspects of the present invention may be shown exaggerated or enlarged to facilitate an understanding of the invention.

A more complete and thorough understanding of the present invention and benefits thereof may be acquired by referring to the following description together with the accompanying drawings, wherein:

FIGS. 1(a) and (b) are schematic drawings showing the cross-sectional view and top view, respectively, of the structure of a carbon nanotube field effect transistor, in accordance with some embodiments.

FIG. 2 is a flow chart showing the processing of carbon nanotube field effect transistors, in accordance with some embodiments.

FIG. 3 is a schematic drawing showing another structure of a carbon nanotube field effect transistor, in accordance with some embodiments.

FIG. 4 is a graph showing the carrier velocity versus drain voltage in the designed carbon nanotube field effect transistor for different channel lengths, in accordance with some embodiments.

FIG. 5 is an I-V graph of the p-type carbon nanotube field effect transistor, in accordance with some embodiments.

FIG. 6 is a trace showing the high frequency performance of the carbon nanotube field effect transistor in frequency domain, in accordance with some embodiments.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### DETAILED DESCRIPTION OF THE INVENTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

The present invention is directed to an apparatus and method of printable carbon nanotube (CNT) field effect transistors (FET).

While most of the terms used herein will be recognizable to those of skill in the art, the following definitions are nevertheless put forth to aid in understanding of the present invention.

“Nanotube,” as defined herein, refers to any tube with nanoscale dimensions.

“Carbon nanotube,” as defined herein, refers to sheets of graphite that form tubes.

“Single-walled nanotube,” as defined herein, refers to a nanotube that does not contain another tube.

“Multi-walled nanotube,” as defined herein, refers to nanotubes within nanotubes.

The present invention incorporates a number of advantages over presently known devices, systems, or processes. These advantages include:

The present invention utilizes the high mobility of carbon nanotube material in field effect transistors. The mobility of the CNT network from our fabricated devices is estimated to be higher than 46,770 cm²/V·s, which is two hundred thirty three times of the mobility of the conventional single crystal silicon (200 cm²/V·s for carrier concentration of 10¹⁹ cm⁻³). John Rogers's sub-monolayer CNT devices exhibit mobilities of 80 cm²/V·s.

The present invention utilizes room temperature inkjet printing of the entire transistor structure, which can be manufactured both on traditional rigid substrate such as silicon wafer and flexible substrate such as plastic.

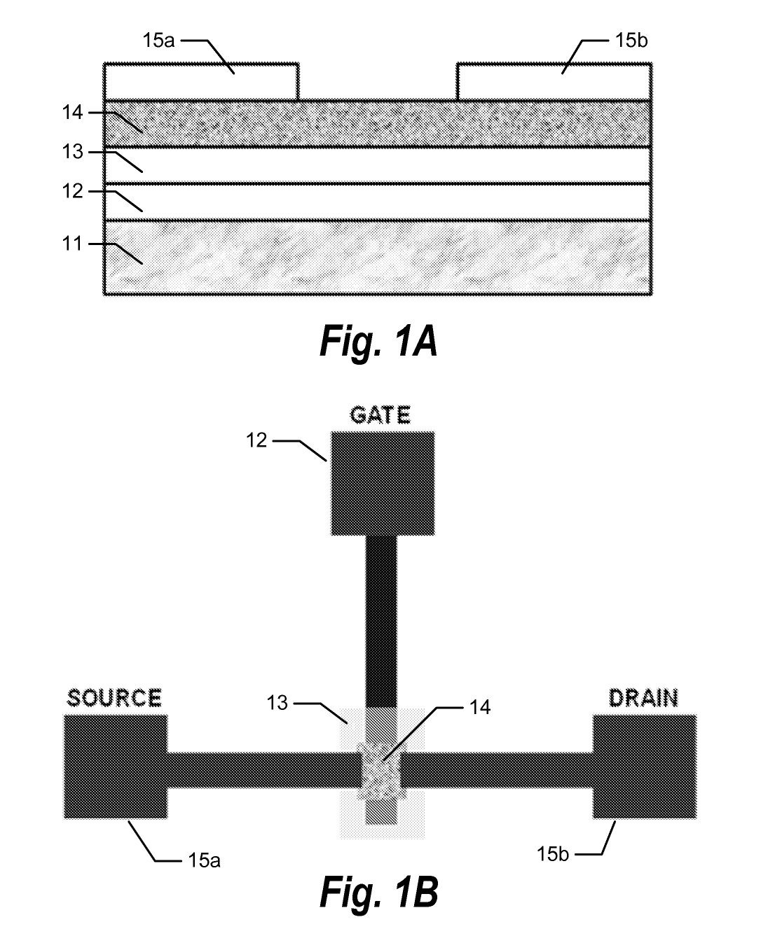

FIGS. 1(a) and (b) are schematic drawings showing the cross-sectional view and top view, respectively, of the structure of a carbon nanotube field effect transistor, in accordance with some embodiments.

In some embodiments, fabrication of a printable carbon nanotube field effect transistor starts with the selection of the substrate 11. The substrate 11 serves as the bottom layer of the CNT-FET and may include, but not be limited to, paper, plastic, indium tin oxide (ITO), glass, metal foil, fabric, and silicon wafer. Next, the gate electrode 12 is printed on top of the substrate 11, with thickness varying from hundreds of nanometers to a few microns depending on the nozzle size and resolution of the inkjet printer. The conductive electrode materials may include, but not be limited to, conductive silver fluids, conductive copper fluids, and conductive ink. Afterwards, the isolation layer 13 is printed above the gate electrode 12. The isolation layer may include, but not be limited to nonconductive fluid such as photoresist. Next, the CNT layer 14 is printed on top of the isolation layer 13. Multiple layers of CNT are printed to reduce the resistance and to build a strong CNT network. The CNT layer 14 serves as the channel layer. At last, source 15a and drain 15b of the transistor are printed on top of the CNT layer 14. The source 15a is an electrode placed above the CNT layer 14 and the drain 15b is an electrode placed above the CNT layer 14. The CNT layer 14 connects source 15a and drain 15b to each other. The isolation layer 13 is used to isolate the gate from the channel CNT layer 14, the source 15a and drain 15b. The top view of the printed layer by layer transistor structure is shown in FIG. 1(b). Unlike the complex alignment required for single CNT transistors, the printing of the just described CNT-FET technique does require any complex alignment. For a single CNT transistor, if the single CNT is not semiconducting, the transistor will not work. Since there are no methods for controlling the growth of the CNT to be metallic or semiconducting, the single CNT transistor device yields are limited to maximum 60%.

In some embodiments, any carbon nanotube can be processed in solvent and be suitable for use in the present invention, including, but not limited to, single-wall nanotubes and multi-wall nanotubes. First, the as-produced CNT is purified to have more than 90% of CNT. Then CNT is dispersed in solvent, either aqueous or organic, with/without agents to help suspension and stability, such as surfactants. The solution is purified by sonication and then centrifuged to remove non-suspended material as has been reported in Haddon et al., U.S. Pat. No. 6,641,793.

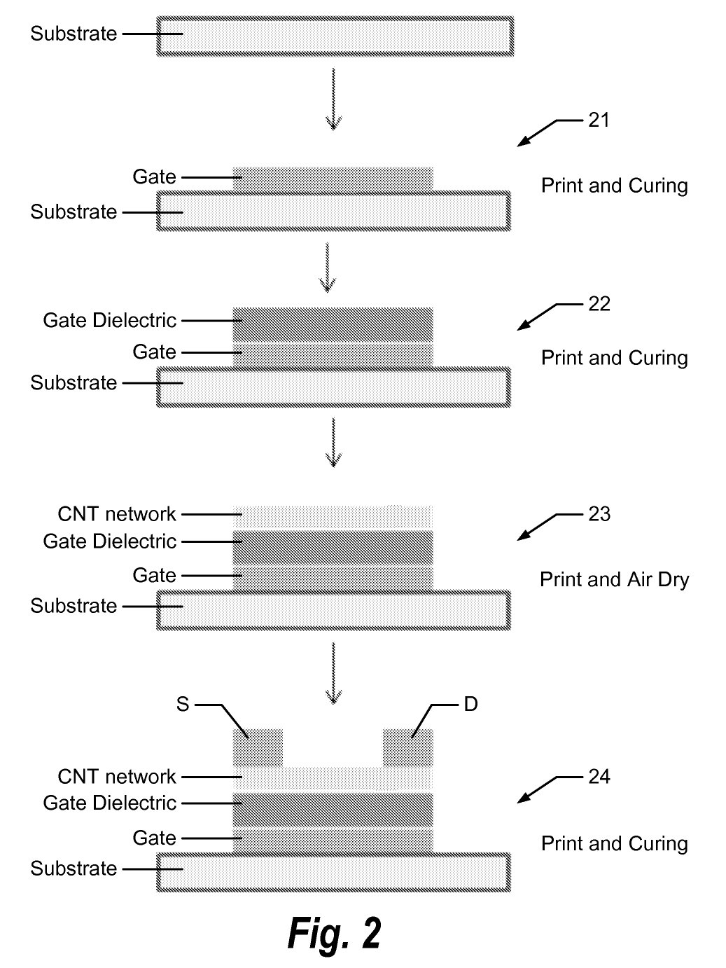

FIG. 2 is a flow chart showing the processing of carbon nanotube field effect transistors, in accordance with some embodiments.

In some embodiments, the process steps of a printed CNT-FET of the present invention are shown in FIG. 2. The steps comprise: printing a metal layer above a flexible or rigid substrate followed by sintering or UV curing depending on the specific silver fluid (step 21). The length and width of the metal layer are defined by the designed geometry in the preloaded graph file sent to the printer. No patterning procedures are needed such as are required for photolithography etching. Then an isolation layer is printed on top of the gate metal followed by air drying or UV curing depending on the specific isolation fluid (step 22). The isolation layer is used to insulate the gate from the other components of the device. Next, a channel layer is printed on top of the dielectric isolation layer (step 23). The channel layer is made of carbon nanotube material. Multiple layers of CNT material can be printed depending on the desired network density and performance of the channel layer. Air drying is followed after the printing of each layer of CNT. At last, the source and drain metal are printed in one step (step 24) followed by sintering or UV curing, with the distance between electrode defined in the graph file sent to the printer. The transistor channel size is determined by the resolution of the printer, which can be as small as 5 microns in the current state of art.

The process of fabricating the CNT-FET utilizes the printing deposition processes. These processes allow for manufacturing on large area substrates, both on flexible or rigid substrates. For flexible substrates, rolls of flexible circuits can be printed, resulting in low cost and high yield.

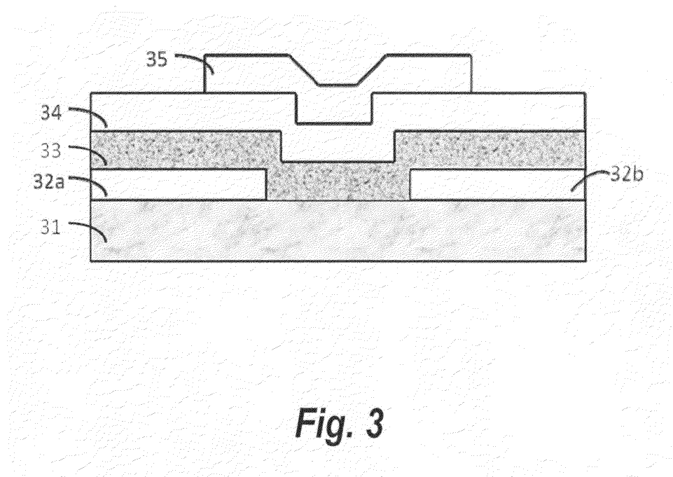

FIG. 3 is a schematic drawing showing another structure of a carbon nanotube field effect transistor, in accordance with some embodiments.

FIG. 3 depicts another feasible device structure. To begin, a substrate 31 is provided as the bottom layer. Then, source 32a and drain 32b of the transistor are printed on top of the substrate 31. Next, the CNT layer 33 is printed on top of the source 32a and drain 32b layer. Multiple layers of CNT are printed to reduce the resistance and to build a strong CNT network. The CNT layer 33 serves as the channel layer, connecting source 32a and drain electrodes 32b. Then, the isolation layer 34 is printed above the CNT layer 33. Lastly, the gate electrode 35 is printed on top of the isolation layer 34. The isolation layer 34 is used to isolate the gate electrode 35 from the channel CNT layer 33, the source 32a, and the drain 32b.

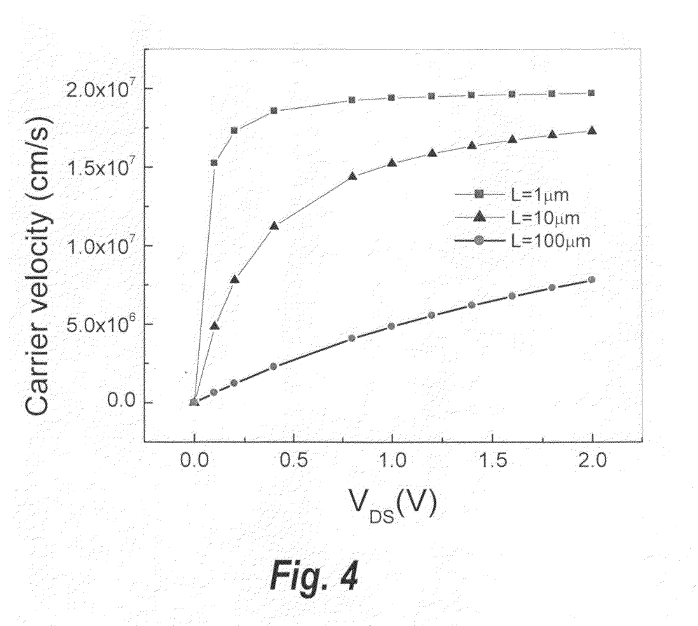

FIG. 4 is a graph showing the carrier velocity versus drain voltage in the designed carbon nanotube field effect transistor for different channel lengths, in accordance with some embodiments.

FIG. 4 shows the calculated carrier velocity of the CNT as a function of drain voltage V_{DS} for channel lengths L of 1 μm, 10 μm, and 100 μm. The carrier velocity is determined by the mobility of the carrier and the saturated velocity of the carrier in CNT, which is around 2×10⁷ cm/s. In this graph, the source-drain voltage ranges from 0 to 2.0 volts. For a 1 μm FET, the carrier velocity saturation voltage is around 0.3 volts. The carrier velocity saturation voltage is 1 volt for a channel length of 10 μm, corresponding to an electrical field of 10³ V/cm. The carrier velocity at this electric field is 1.5×10⁷ cm/s.

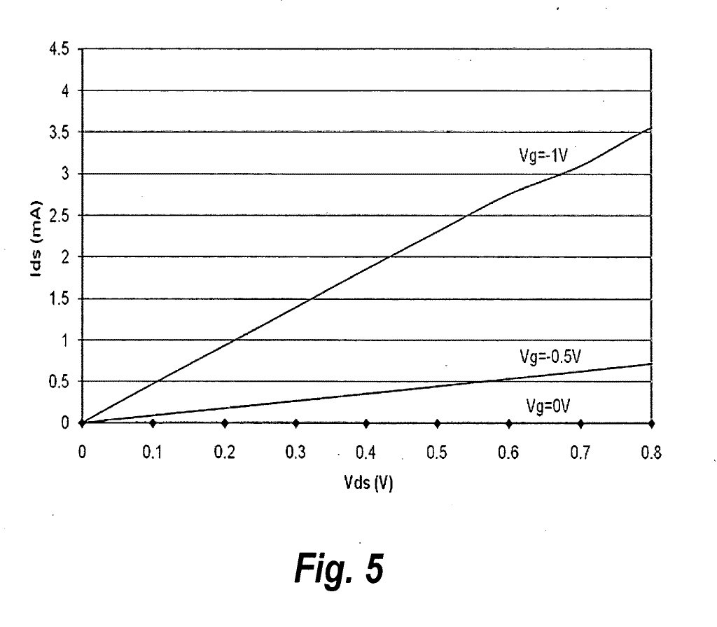

FIG. 5 is an I-V graph of the p-type carbon nanotube field effect transistor, in accordance with some embodiments.

In some embodiments, the gate voltage is used to control the resistance of the CNT channel layer between the source and drain. Slight changes in the gate voltage can make dramatic changes in the conductivity of the channel layer. FIG. 5 shows the graph of a measured I-V curve showing the CNT-FET as recited above. The horizontal axis represents the source and drain voltages, and the vertical axis represents the current generated from the drain at different gate voltages. The traces are measured under gate voltages of −1 volt, −0.5 volt and 0 volt, respectively. The FET is fully turned off at a zero volt gate voltage. No gate leakage current was measured. Note that the source-drain current is in the 4 mA range, a much higher current range than conventional organic FETs, which are typically in the micro amp or nano amp range.

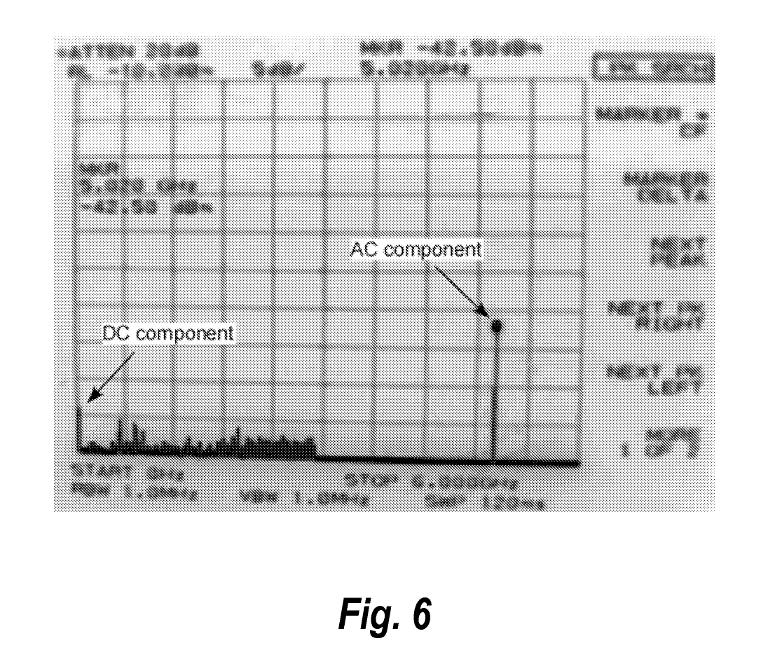

Because of the high field-effect mobility, the operation frequency of the circuit can be as high as tens of GHz. FIG. 6 is a trace showing the high frequency performance of the carbon nanotube field effect transistor in frequency domain, in accordance with some embodiments. The horizontal axis is the frequency and the vertical axis represents the power level. The left peak is the DC component of the output signal from the transistor and the center peak of the spectrum is the 5 GHz AC component of the output signal from the transistor.

In summary, the present invention provides an apparatus and manufacturing process for network based CNT, instead of single based CNT, field effect transistors for high speed applications, utilizing the ultra high carrier mobility of CNT. The invention enables fast and low cost manufacturing methods for flexible electronics.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed within the following claims.

1. A method for manufacturing carbon nanotube based field effect transistors, the method comprising:
providing a substrate;
using a conductive fluid to print a gate electrode layer onto the substrate;
sintering and/or UV curing the gate electrode layer;
using a nonconductive fluid to print a gate isolation layer onto the gate electrode;
air drying and/or UV curing the gate isolation layer;
using a carbon nanotube solution to print one or more carbon nanotube channel layers onto the gate isolation layer, wherein each carbon nanotube channel layer is air dried prior to subsequent printings;
using the conductive fluid to print a source and drain electrode layer onto the one or more carbon nanotube channel layers; and
sintering and/or UV curing the source and drain electrode layer.

2. The method of claim 1, where the substrate comprises at least one of: paper, plastic, ITO, glass, metal foil, fabric, and silicon wafer.

3. The method of claim 1, where the conductive fluid comprises at least one of: silver, copper, gold, and ink.

4. The method of claim 1, where the nonconductive fluid comprises photoresist.

5. The method of claim 1, where the carbon nanotube solution comprises at least one of:
single-wall nanotube and multi-wall nanotubes.

6. The method of claim 1, where the one or more carbon nanotube channel layers are semiconducting.

7. A method for manufacturing carbon nanotube based field effect transistors, the method comprising:
providing a substrate;
using a conductive fluid to print a source and drain electrode layer onto the substrate;
sintering and/or UV curing the source and drain electrode layer;
using a carbon nanotube solution to print one or more carbon nanotube channel layers onto the source and drain electrode layer, wherein each carbon nanotube channel layer is air dried prior to subsequent printings;
using a nonconductive fluid to print a gate isolation layer onto the one or more carbon nanotube channel layers;
air drying and/or UV curing the gate isolation layer;
using the conductive fluid to print a gate electrode layer onto the gate isolation layer; and
sintering and/or UV curing the gate electrode layer.

8. The method of claim 7, where the substrate comprises at least one of: paper, plastic, ITO, glass, metal foil, fabric, and silicon wafer.

9. The method of claim 7, where the conductive fluid comprises at least one of: silver, copper, gold, and ink.

10. The method of claim 7, where the nonconductive fluid comprises photoresist.

11. The method of claim 7, where the carbon nanotube solution comprises at least one of: single-wall nanotube and multi-wall nanotubes.

12. The method of claim 7, where the one or more carbon nanotube channel layers are semiconducting.

13. A semiconductor device comprising a carbon nanotube field effect transistor, where the carbon nanotube field effect transistor is fabricated by:
providing a substrate;
using a conductive fluid to print a gate electrode layer onto the substrate;
sintering and/or UV curing the gate electrode layer;
using a nonconductive fluid to print a gate isolation layer onto the gate electrode;
air drying and/or UV curing the gate isolation layer;
using a carbon nanotube solution to print one or more carbon nanotube channel layers onto the gate isolation layer, wherein each carbon nanotube channel layer is air dried prior to subsequent printings;
using the conductive fluid to print a source and drain electrode layer onto the one or more carbon nanotube channel layers; and
sintering and/or UV curing the source and drain electrode layer.

14. The semiconductor device of claim 13, where the substrate comprises at least one of: paper, plastic, ITO, glass, metal foil, fabric, and silicon wafer.

15. The semiconductor device of claim 13, where the conductive fluid comprises at least one of: silver, copper, gold, and ink.

16. The semiconductor device of claim 13, where the one or more carbon nanotube channel layers are semiconducting.

17. A semiconductor device comprising a carbon nanotube field effect transistor, where the carbon nanotube field effect transistor is fabricated by:
providing a substrate;
using a conductive fluid to print a source and drain electrode layer onto the substrate;
sintering and/or UV curing the source and drain electrode layer;
using a carbon nanotube solution to print one or more carbon nanotube channel layers onto the source and drain electrode layer, wherein each carbon nanotube channel layer is air dried prior to subsequent printings;
using a nonconductive fluid to print a gate isolation layer onto the one or more carbon nanotube channel layers;
air drying and/or UV curing the gate isolation layer;
using the conductive fluid to print a gate electrode layer onto the gate isolation layer; and
sintering and/or UV curing the gate electrode layer.

18. The semiconductor device of claim 17, where the substrate comprises at least one of: paper, plastic, ITO, glass, metal foil, fabric, and silicon wafer.

19. The semiconductor device of claim 17, where the conductive fluid comprises at least one of: silver, copper, gold, and ink.

20. The method of claim 17, where the nonconductive fluid comprises photoresist.

21. The method of claim 17, where the carbon nanotube solution comprises at least one of: single-wall nanotube and multi-wall nanotubes.

22. The semiconductor device of claim 17, where the one or more carbon nanotube channel layers are semiconducting.
